(19) United States
(12) Patent Application Publication
(10) Pub. No.: US 2002/0079057 A1
(43) Pub. Date: Jun. 27, 2002

(54) Apparatus for processing specimens

(76) Inventors: Ken Yoshioka, Hikari-shi (JP); Yoshimi Torii, Tokyo (JP); Moriaki Fuyama, Hitachi-shi (JP); Tomohiro Okada, Odawara-shi (JP); Saburou Kanai, Hikari-shi (JP); Takehito Usui, Niihari-gun (JP); Hitoshi Harata, Utsunomiya-shi (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 10/083,353

(22) Filed: Feb. 27, 2002

Related U.S. Application Data
(62) Division of application No. 09/493,104, filed on Jan. 28, 2000.

(30) Foreign Application Priority Data
Oct. 8, 1999 (JP) 11-288657

(51) Int. Cl. C23F 1/00; C23C 16/00

(52) U.S. Cl. 156/345.31; 118/719

(57) ABSTRACT

A method of processing a specimen, an apparatus therefor and a method of manufacture of a magnetic head using the same are provided, featuring a high etching rate at a low specimen temperature, and a simple corrosion prevention treatment for removing a residual chlorine component by liquid rinsing, and thereby eliminating provision of a post treatment step to remove a corrosion product. The method comprises the steps of: forming a lamination layer comprising a seed layer of NiFe alloy, an upper magnetic pole of NiFe alloy connected to the seed layer, a gas layer of an oxide film in close contact with the seed layer, and a shield layer of NiFe alloy in close contact with the gap layer; plasma-etching the seed layer using a gas which contains chlorine with the upper magnetic pole used as its mask; and removing a residual chlorine component by liquid rinsing, following by a drying process.

This application is a Divisional application of application Ser. No. 09/493,104, filed Jan. 28, 2000.

### BACKGROUND OF THE INVENTION

The present invention relates to a method of processing specimens by plasma etching, an apparatus therefor and a method of manufacture of a magnetic head using the same.

A specimen, such as a substrate of a semiconductor device, is subjected to etching processing, for example, using a chemical solution or by plasma etching. In such etching processing of the specimen, adequate care must be taken to prevent corrosion of the specimen after etching processing.

An anti-corrosion technique for use after the etching processing of the specimen is disclosed, for example, in JP-A Laid-Open No. 59-186326, wherein a residual chlorine compound, which is a corrosive substance remaining in a resist film and the like, is oxidized by ashing process for ashing the resist film using a plasma in a plasma processing chamber which is connected to an etching chamber and is maintained in a vacuum. Further, it is also known that by heating the specimen after etching to a temperature above 200° C., evaporation of a residual chlorine substance, which is corrosive material remaining in the specimen, is promoted, thereby preventing corrosion of the substance after the etching process. Still another process is disclosed in JP-A Laid-Open No. 61-133388, wherein a specimen to be treated after etching is taken out of an etching chamber, transferred to a heat treatment chamber, dried by heated air, and then is taken out of the heat treatment chamber to be rinsed and dried, thereby attempting to prevent corrosion of the specimen due to reaction with the atmosphere after etching.

JP-A -L-aid-Open No. 2-224233 discloses a method of processing specimens, comprising: a first step of processing a laminated specimen which includes metals, each having a different ionization tendency, by gas plasma etching using a first gas plasma via a resist mask formed on the lamination in a first processing chamber; a second step of processing the specimen using a second gas plasma, which is formed in a gas atmosphere different from that of the first gas plasma in a second processing chamber, for removing the resist mask and residual corrosive substances formed in the first step and deposited on a surface of side walls of the lamination including different ionization metals; and a third step of rinsing the surface of the specimen which is exposed by the first and the second steps with at least one liquid for removing a remaining part of the residual corrosive substances deposited on the side wall of the lamination which could not have been removed by the second step. According to this method, in the f first step, the specimen formed by laminating an Al alloy film and a TiW or TiN film is subjected to etching via a resist mask in a vacuum using a gasplasma which contains chlorine; in the second step, the specimen is subjected to a ashing process using a gas plasma which contains chlorine; and in the third step, the specimen is rinsed in water, and wherein the third step is comprised of either one of the following four steps in order to remove a residual corrosive product remaining after the first step: (a) rinsing in water; (b) rinsing in water after rinsing in alkaline liquid; (c) rinsing in water after rinsing in acid liquid; and (d) rinsing in water after rinsing in fluorine nitric acid.

A method of etching a material for use in a thin film magnetic head, magnetic sensor and the like which contains Fe is disclosed in JP-A-4-107281. This method of etching the material which contains Fe is directed to etching such a material as Fe-containing an alloy formed on a surface of the specimen, and in particular, a Fe—Si—Al alloy, and is comprised of the steps of: etching the specimen by reactive ion milling in chlorine gas by heating the specimen above 250° C. and below a melting point thereof in a vacuum; a post treatment process for causing a residual substance remaining on the surface of the specimen completely to react with the chlorine gas by holding the specimen at a temperature above 250° C. and by applying a chlorine ion shower to the specimen; and a pure water treatment process for dissolving and removing an etching product produced in the post treatment process by holding the specimen in pure water, wherein these steps are executed in the sequence as described above.

However, there is a problem associated with the method of JP-A-Publication No.4-107281 in that, when etching pure Fe, for example, of 3 μm thick, by argon ion milling for constructing a magnetic head, because its etching rate is approximately 150A/min., the etching time is as long as 200 min. This is because that the number of incident ions controls the etching rate. Therefore, in order to improve the etching rate, the specimen is heated above 250° C., and the reactive ion milling method is applied in an atmosphere of chlorine gas in JP-A Laid Open No. 4-107281, thereby improving the etching rate approximately to a level of 1000A/min. However, there arise problems in that, depending on the type of specimen, the specimen may not be able to withstand a temperature above 250° C., thereby preventing application of the above-mentioned method in such a case. In particular, in the case of etching a lamination film which includes a ferromagnetic material such as NiFe alloy which is used in manufacture of a magnetic head, if the temperature of its specimen rises above 230° C., the magnetic property of the NiFe film is deteriorated, such that it cannot be recovered even when its temperature returns to normal, or a remagnetization process is required for recovering the initial magnetic property.

Further, in JP-A Laid-Open No. 4-107281, because the specimen tends to corrode when left in the atmosphere after the reactive ion milling, a corrosion prevention process is proposed, which includes a post treatment step for applying a chlorine ion shower to the specimen which is kept at a high temperature above 250° C. and a pure water treatment step for submerging the specimen in pure water after the post treatment. However, there are problems with this proposal as well, in that a temperature above 250° C. is required for the specimen once again, and a complicated corrosion prevention sequence of the ion shower step followed by the pure water submersion step is required, thereby increasing the cost.

The above-mentioned complicated corrosion prevention procedure is considered to be necessary because the target specimen, which is an Fe—Si—Al alloy, contains two different metals having a largely different ionization tendency from each other, and therefore, is highly corrosive as described in JPA Laid Open No. 2-224233.

Further, the lamination film thereof, as formed and to be processed in the manufacture of the magnetic head, generally includes an oxide film of NiFe alloy, alumina, silicon oxide or the like, thereby allowing for a reaction product resulting from etching of these films by milling, plasma etching or the like to deposit on the surface of the side walls of the etched lamination. This film on the sidewalls causes a problem when etching the lamination continuously by impeding a subsequent etching process, thereby rendering it difficult to carry out a vertical processing.

### SUMMARY OF THE INVENTION

An object of the invention is to provide for a method of processing a specimen formed of a lamination film which includes a Ni—Fe alloy, characterized in that the lamination can be etched at an improved etching rate and at a low temperature which prevents break-down of the device, so that a simple and low cost corrosion prevention treatment is provided, and, at the same time, the deposition film on the side walls can be efficiently removed, thereby ensuring that a continuous and vertical etching of the lamination will be carried out, and to provide for an apparatus therefor and also a method of manufacture of a magnetic head using the same.

The feature of the present invention resides in combining a step of plasma etching of a specimen, such as a magnetic pole of a magnetic head, which is formed of Ni—Fe alloy, using a relatively high density plasma source and a gas which contains chlorine and/or fluorine nitric acid, and a step of rinsing the specimen in a liquid and drying it immediately after the etching processing.

The above-mentioned high density plasma source refers to an induction coupling type plasma apparatus, helicon type plasma apparatus, two-frequency excitation parallel plane type plasma apparatus, microwave type plasma apparatus and the like, which can generate a plasma having a saturated ion current density of approximately 1-10 mA/cm². This type of apparatus has a plasma density as high as 10 to 100 times compared to low density plasma of conventional milling and parallel plane type apparatuses. Further, in these types of high density plasma sources, another high frequency power source separate from the high frequency power source for plasma generation is provided for the specimen stage, which can be controlled independently of an ion energy of incidence on the specimen. When this plasma source is applied, because of an increased number of incident ions, even if the setting of the incident ion energy is decreased to as low as 50-500 eV, that is, ½ to one tenth of the values for the milling method, and the temperature of the specimen is decreased, a high etching rate becomes possible. For example, at a temperature of 40° C. of the specimen and at an ion energy of 300 eV, an etching rate of 100 nm/min can be realized. If the temperature of the specimen is in the range of 40 to 60° C., there is another advantage in that the design of the specimen stage can be simplified contributing to the reduction of cost.

Further, because of a shallow penetration depth of the bombarded chlorine ions into the Ni—Fe alloy layer due to a low bombardment ion energy in the high density plasma processing according to the invention, and because Ni and Fe are identical metals having an identical ionization tendency which is immune to the corrosion mechanism due to different ionization tendencies, as described above, a corrosion prevention can be realized by simply removing residual chlorine components deposited on the surface layer of the specimen, thereby providing for a simple and low cost corrosion prevention means of the invention.

Still further, the lamination layer which is prepared for manufacture of a magnetic head includes, in addition to the Ni—Fe alloy layer, various other layers, such as a layer of alumina or silicon oxide, a photo resist layer and the like, which must be processed by etching using high density plasma. During the etching processing of the lamination layer, the Ni—le alloy layer is exposed to plasma from the under-layer, or using the Ni—Fe alloy layer itself as a mask, the oxide film layer or the like is etched. In this instance also, the Ni—Fe alloy layer is exposed to a chlorine or fluorine plasma atmosphere, thereby needing a post etching treatment for corrosion prevention of the specimen. The corrosion prevention treatment by means of liquid rinsing according to the invention is effective to these etching steps described above.

Furthermore, during etching of the lamination layer for manufacture of a magnetic head, a reaction product tends to deposit on both sidewalls of the lamination layer to be etched. Therefore, there arises a problem in that this reaction product deposited on the both sidewalls prevents a subsequent etching process from being continued, thereby impeding the continuous and vertical etching of the lamination layer. However, according to the invention, these reaction product deposits can be removed easily by the liquid rinsing treatment immediately after etching. Therefore, if an etching unit and a liquid rinsing/drying unit are provided in combination in one apparatus allowing for their continuous operation and treatment, and if this liquid rinsing treatment is inserted between each etching processing, an efficient and continuous etching can be achieved in one single apparatus.

More specifically, the instant invention provides for the following methods and apparatuses therefor.

The invention provides for a method of processing a specimen formed of a lamination layer which includes at least one layer of Ni—Fe alloy or Ni—Fe—Co alloy formed on a substrate, comprising: a first step for etching the lamination layer by a gas plasma including a gas which contains chlorine at a temperature of the specimen below 200° C. in an etching chamber; a second step of removing a residual chlorine compound which is deposited on a sidewall of the lamination layer which is exposed by the first step, by rinsing the same in at least one liquid; and a third step of drying the side wall thereof after rinsing.

The invention, further, provides for the above-referenced method of processing the specimen, wherein the second step is executed continuously after the first step.

The invention provides for the method of processing the specimen, wherein the gas plasma is produced using at least one species of, gas selected from the group consisting of Cl₂, BCl₃, Ar and O₂ or a combination thereof.

The invention, further, provides for the method foregoing of processing the specimen, wherein the second step of liquid rinsing is comprised of one or more of the following steps:

(A) a pure water rinsing;

(B) water rinsing after alkaline liquid rinsing;

(C) water rinsing after acid liquid rinsing;

(D) water rinsing after fluorine nitric acid rinsing (resist developer solution TMAH); and

(E) water rinsing after neutral detergent cleaning.

Further, the invention provides for the foregoing method of processing the specimen, wherein the third step of drying is executed at a temperature below 200° C.

Still further, the invention provides for the foregoing method of processing the specimen, wherein the temperature of the liquids used are controlled of their temperatures.

Furthermore, the invention provides for the method of processing the specimen, wherein the lamination layer of the specimen includes as other layers at least one of the following layers which are to be subjected to gas plasma etching in the processing chamber:

(A) a photo resist layer;

(B) alumina (Al₂O₃) layer;

(C) silicon oxide layer;

(D) Cu layer; and

(E) Ta layer.

Furthermore, the invention provides for the method of processing the specimen, wherein the substrate is formed of Al₂O₃/TiC, on which substrate a Ni—Fe alloy or Ni—Fe—Co alloy layer is formed, which is etched by gas plasma in the processing chamber.

The invention provides for an apparatus for etching a specimen having a lamination layer formed on a substrate using gas plasma in a processing chamber, comprising: an etching process chamber to which a gas is supplied to produce a plasma, and the lamination layer having more than two layers including at least one layer of Ni—Fe alloy or Ni—Fe—Co alloy formed on the substrate is etched therein at a temperature of the specimen below 200° C.; a rinsing unit for rinsing in a liquid a portion of the lamination layer including the Ni—Fe alloy and is exposed to the atmosphere by the etching process; and a dryer unit for drying the portion of the lamination layer including the Ni—Fe alloy which is exposed, wherein the lamination layer of Ni—Fe alloy which is dried is further subjected to subsequent etching using a gas plasma.

The present invention also provides for an apparatus for processing a specimen,, comprising: an atmospheric loader; a vacuum transport chamber with a vacuum transport robot provided therein; unload and load lock chambers which connect between the atmospheric loader and the vacuum transport chamber; and an etching process chamber of the etching process apparatus which is connected to the vacuum transport chamber, wherein the atmospheric loader is provided with a rinsing cup, hot plate and the like of the rinsing and drying unit connected thereto.

According to another aspect of the invention, a plurality of etching chambers are provided in the apparatus for processing the specimen.

According to still another aspect of the invention, a method of manufacture of a magnetic head having an upper magnetic pole and a lower magnetic pole disposed opposite thereto is comprised of the steps of: forming a lamination layer including an upper photo resist layer, a hard mask layer made of SiO₂ or alumina, a lower photo resist layer and a seed layer made of Ni—Fe alloy or Ni—Fe—Co alloy; etching the hard mask layer by plasma processing using the upper photo resist layer as a mask; further etching the lower photo resist layer by plasma processing using a gas which contains chlorine with the hard mask used as a mask such that a deep groove is formed until the seed layer is exposed in the bottom of the deep groove; removing a residual chlorine compound deposited on the surface of the seed layer which is exposed by rinsing it with a liquid; drying the rinsed surface; and after that, embedding a Ni—Fe alloy into the deep groove which makes contact with the seed layer.

According to a still further aspect of the invention, a method of manufacture of a magnetic head having a structure of an upper magnetic pole and a lower magnetic pole disposed opposite thereto is comprised of the steps of: forming a lamination layer including a seed layer made of Ni—Fe alloy or Ni—Fe—Co alloy, an upper magnetic pole made of Ni—Fe alloy in close contact with the seed layer, a gap layer of an oxide film in close contact with the seed layer, and a shield layer made of Ni—Fe alloy in close contact with the gap layer; etching the seed layer using the upper magnetic pole as a mask with a gas which contains chlorine by plasma etching; and after that, removing a residual chlorine compound using a liquid.

Further, according to the invention, a method of manufacture of a magnetic head which has a structure of an upper magnetic pole and a lower magnetic pole disposed opposite thereto is comprised of the steps of: forming a lamination layer which includes a seed layer made of Ni—Fe alloy or Ni—Fe—Co alloy and an upper magnetic pole made of Ni—Fe alloy connected with the seed layer, a gap layer made of an oxide film in close contact with the seed layer, and a shield layer made of Ni—Fe alloy in close contact with the gap layer; etching the seed layer; etching the gap layer by plasma etching using the upper magnetic pole as a mask and with a gas which contains chlorine or fluorine; and then removing a residual chlorine compound by rinsing with a liquid.

According to a still further aspect of the invention, a method of manufacture of a magnetic head having a structure of an upper magnetic pole and a lower magnetic pole disposed opposite thereto is comprised of the steps of: forming a lamination layer which includes a seed layer made of Ni—Fe alloy or Ni—Fe—Co alloy and an upper magnetic pole made of Ni—Fe alloy connected with the seed layer, a gap layer made of an oxide film in close contact with the seed layer, and a shield layer made of Ni—Fe alloy in close contact with the gap layer; etching the seed layer; etching the gap layer; trim-etching the shield layer using the upper magnetic pole as a mask and with a gas containing chlorine by plasma processing; and then removing a residual chlorine compound by rinsing with a liquid.

According to still another aspect of the invention, a method of manufacture of a magnetic head having a structure of an upper magnetic pole and a lower magnetic pole disposed opposite thereto is comprised of the steps of: forming a lamination layer which includes a seed layer made of Ni—Fe alloy or Ni—Fe—Co alloy and an upper magnetic pole made of Ni—Fe alloy connected with the seed layer, a gap layer made of an oxide film in close contact with the seed layer, and a shield layer made of Ni—Fe alloy in close contact with the gap layer; etching the seed layer, the gap layer and the shield layer, respectively, using the upper magnetic pole as a mask by plasma etching exclusively in a vertical direction; and executing a corrosion prevention treatment to remove a residual chlorine compound deposited on an etched surface.

In the method of manufacture of a magnetic head according to the invention, the gap layer is processed by plasma etching with a gas which contains chlorine or fluorine, and the seed layer and the shield layer are processed by plasma etching with a gas which contains chlorine and argon gases, and further the corrosion prevention treatment is executed by rinsing using a liquid.

The invention provides for a method of manufacture of a magnetic head having a structure of an upper magnetic pole and a lower magnetic pole disposed opposite thereto, the method being comprised of the steps of: forming a lamination layer which includes a seed layer made of Ni—Fe alloy or Ni—Fe—Co alloy and an upper magnetic pole made of Ni—Fe alloy connected with the seed layer, a gap layer made of an oxide film in close contact with the seed layer, and a shield layer made of Ni—Fe alloy in close contact with the gap layer; etching the seed layer and the gap layer continuously by plasma etching using the upper magnetic pole as a mask; and then executing a corrosion prevention treatment for removing a residual chlorine compound deposited on an etched surface.

The invention provides for a method of manufacture of a magnetic head having a structure of an upper magnetic pole and a lower magnetic pole disposed opposite thereto, and in particular, a method of manufacture of the upper magnetic pole thereof, the method thereof being comprised of the steps of: forming a lamination layer which includes an upper magnetic layer made of Ni—Fe alloy, and a mask layer made of an oxide film such as photo resist or alumina, a silicon oxide and the like; etching the upper magnetic pole layer by plasma etching with the mask layer used as a mask; and then, executing a corrosion prevention treatment for removing a residual chlorine compound deposited on an etched surface.

Further, the invention provides for a method of processing an upper magnetic pole of a magnetic head having a structure of an upper magnetic pole and a lower magnetic pole disposed opposite thereto, the method being comprised of the steps of: forming, from the above,

(A) a photo resist film,

(B) an oxide layer such as alumina, silicon oxide or the like,

(C) an upper magnetic pole layer made of Ni—Fe alloy,

(D) a seed layer made of Ni—Fe—Co alloy for bonding Ni—Fe alloy,

(E) a gap layer made of an oxide film such as alumina, silicon oxide or the like, and

(F) a shield layer made of Ni—Fe alloy;

executing the following plasma process steps continuously

(1) etching the oxide film layer using the mask layer as its mask,

(2) etching the upper magnetic pole layer using the oxide film layer as a mask,

(3) etching the seed layer using the oxide film layer or the upper magnetic pole layer as a mask,

(4) etching the gap layer using the oxide film layer and the upper magnetic pole layer, and

(5) trim-etching the shield layer using the oxide film layer and the upper magnetic pole layer as a mask; and then

executing a corrosion prevention treatment for removing a residual chlorine compound deposited on an etched surface.

According to still another aspect of the invention, in the method of manufacture of the magnetic head described above, any portions of the plasma process steps (1)-(5) may be selected, combined and executed sequentially, and after that the corrosion prevention treatment for removing the residual chlorine compound may be executed.

According to a further aspect of the invention described above, the steps of rinsing and drying for removal of residual chlorine components and deposits on the side wall may be executed after each step of the plasma process steps (1)-(5), which are continuously executed in a single apparatus.

According to still another aspect of the invention, the method of manufacture of the magnetic head described above is characterized in that the etching process of step (1) is executed using a gas which contains mainly BCl₃ or fluorine, steps (2) and (3) are executed using a gas which contains mainly chlorine, step (4) is executed using a gas which contains mainly BCl3 or fluorine, and step (5) is executed using a gas which contains mainly chlorine, in order to increase the selectivity ratio between the mask and under-layers during each etching processing step.

### BRIEF DESCRIPTION OF THE DRAWINGS

The other features and advantages of the invention will be apparent from the following description taken in connection with the accompanying drawings, in which:

FIG. 1 is a diagram showing a top view of one embodiment of the invention;

FIG. 2 is a diagram showing a front view of units in a vacuum of apparatus in FIG. 1;

FIG. 3 is a diagram showing a cross-section of an etching chamber;

FIG. 4 is a perspective view in part of the etching chamber of FIG. 3;

FIG. 5 is a diagram for explaining a process flow of the embodiment of the invention;

FIG. 6 is a perspective view of a magnetic head according to the invention;

FIG. 7 is a flow diagram showing the process of forming an upper magnetic pole by three-layer resist etching according to the invention;

FIG. 8 is a flow diagram showing the vertical forming of a seed layer of Ni—Fe a gap layer of Al203, and a shield under-layer of NiFe of the invention;

FIG. 9 is a process flow diagram of another embodiment of the invention, showing its steps of manufacture;

FIG. 10 is a diagram which illustrates an advantage and effect of rinsing of the invention;

FIG. 11 is a table which shows a result of experiments according to the invention; and

FIG. 12 is a table which compares the results of the present invention to results obtained using a milling process.

### PREFERRED EMBODIMENT

An embodiment of the invention will be described more in detail with reference to the accompanying drawings.

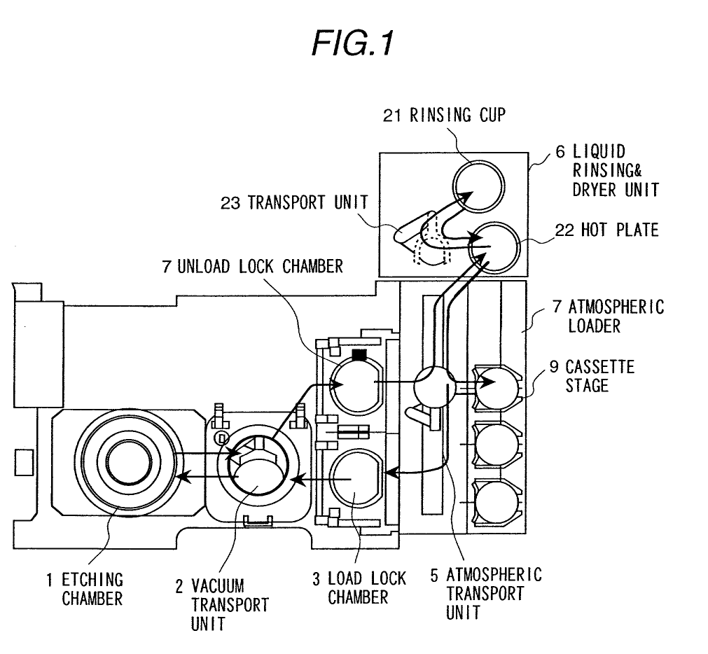

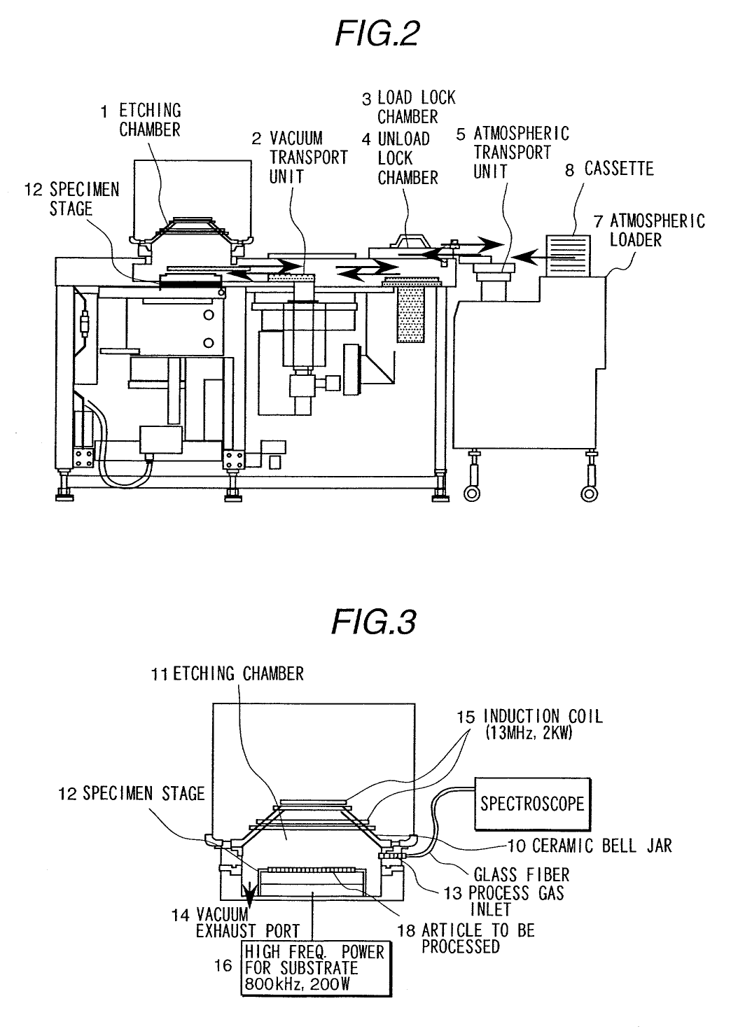

FIG. 1 shows a schematic arrangement of one embodiment of the invention, and FIG. 2 shows a cross-section of portions in vacuum in the arrangement of FIG. 1. In these figures, an apparatus for processing specimens according to the invention is provided with an etching process unit 1, a vacuum transport unit 2, a load lock chamber 3, an unload lock chamber 4, an atmospheric transport unit 5, a rinsing/drying unit 6, an atmospheric loader 7, and a cassette table 8.

As etching process unit 1, an etching device for etching the specimen using a plasma in a vacuum is used. By way of example, for its plasma etching process, an induction coupling type plasma etching apparatus, a helicon type plasma etching apparatus, a two-frequency excitation parallel plane type plasma etching apparatus, a microwave plasma etching apparatus or the like are adopted.

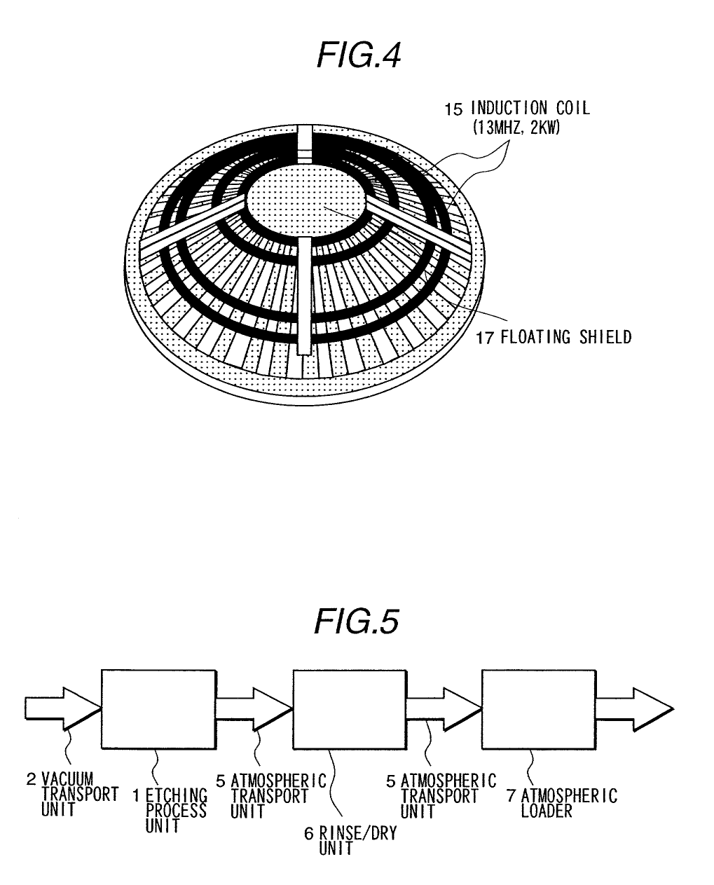

FIG. 3 is a schematic diagram illustrating the etching process unit 1 of the invention, and FIG. 4 is a perspective view of the etching process unit 1.

With reference to FIG. 3, etching process unit 1 is provided with: an etching process chamber 11 in the form of an alumina ceramic or quartz bell jar 10; specimen stage 12; process gas inlet portion 13; vacuum exhaust portion 14; and induction coil 15 (for example, of 13 MHz, 2kW), wherein on specimen stage 12, an article 18 such as a magnetic pole material to be processed is mounted, which will be described later. Further, a high frequency unit 16 capable of outputting, for example, 800kHz, 200W is connect d to the specimen stage 12.

With reference to FIG. 1, rinsing/drying unit 6 is provided with rinsing cup 21, hot plate 22 and transfer device 23. For water rinsing, a spinning type wet process device is used.

In the spinning wet process device for rinsing, the specimen after post treatment undergoes, for example, water spinning rinsing or chemical solution spinning rinsing followed by water spinning rinsing. In this case, the chemical solution is selected appropriately depending on the type of material to be removed from the specimen after post-treatment. Further, as its process atmosphere, an inactive gas atmosphere such as nitrogen gas or the like, or even air may be used. Also, after this wet processing, a drying process by water spinning or the like may be adopted.

As its drying process device, a dryer for drying the specimen after it has been subjected to wet processing in the wet process device by heating the same, or a blower for drying the specimen by blowing a dry gas or the like, is used. Further, as its process atmosphere, nitrogen gas or air may be used.

Vacuum transport unit 2 operates to transport a processed specimen between a process station (not indicated) of etching process unit 1 and load lock chamber 3 or unload lock chamber 4. Atmospheric transport unit 5 operates to transport the processed specimen between load lock chamber 3 or unload lock chamber 4 and rinsing/drying unit 6. Transport device 23 operates to transfer a wet-processed specimen between a process station (not indicated) of the wet process unit and a process station (not indicated) of the drying process unit. As the specimen transport device, any prior art transport device may be adopted, including, for example, those having a gripper to grip a specimen at its periphery, a scooper to hold the specimen thereon, a magnetic chuck, a vacuum chuck or the like each attached to an arm which is mechanically, electrically or magnetically actuated, a belt transport device wound around a main drive roller and a follower roller, or an air blower transport device may be used. Vacuum transport unit 2 is arranged such that, when the etching process unit 1 is a device which processes the specimen using plasma in a vacuum, the processed specimen is ensured to be transported without being exposed to the atmosphere, with the same being contained in a vacuum.

Atmospheric transport unit 6 has also a function to transport the specimen which is transported from unload lock chamber 4 to dryer unit 6 and to be dried therein such that the specimen is collected by cassette 8 which is mounted on cassette table 9.

In case the etching process unit 1 is a device which processes a specimen using plasma in a vacuum, a specimen's processing atmosphere in etching process unit 1 and a space through which a specimen to be processed is transported or a space through which a specimen having been processed is transported are arranged to be communicative with each other and/or interruptible. Further, the space through which the specimen is transported, the specimen's wet process atmosphere in the wet processing unit, a space through which a wet-processed specimen is transported, the specimen's drying process atmosphere in the dryer unit, and a space through which a drying processed specimen is transported may be arranged to be in communication with each other or interruptible.

A process station is provided in etching process unit 1. In the case where etching process unit 1 is a device, which processes the specimen using plasma in a vacuum, its process station is a specimen stage 12. One or a plurality of specimens may be mounted on this specimen stage 12.

If etching is to applied to a plurality of lamination films sequentially, and a liquid rinsing is required for removing residual deposits on the etched side wall after each etching step, the specimen delivered from the hot plate is transported again to the load lock chamber without being collected by the cassette.

With reference to FIG. 5, specimen transport devices such as vacuum transport device 2 and atmospheric transport device 5 are provided between etching process unit 1, rinsing/drying unit 6 and atmospheric loader 7. Vacuum transport unit 5 has a vacuum transport chamber in which a vacuum transport robot (not indicated) is provided.

In the case where the seed layer, the gap layer and the shield layer are to be processed continuously, and at the same time corrosion prevention/deposit removal processing is to be applied after each step of the above, the specimen is returned from the atmospheric loader 7 to the vacuum transport unit 2 in repetition as indicated in FIG. 5.

Now, an example of a specimen where a magnetic pole of a magnetic-head is to be formed will be described in the following.

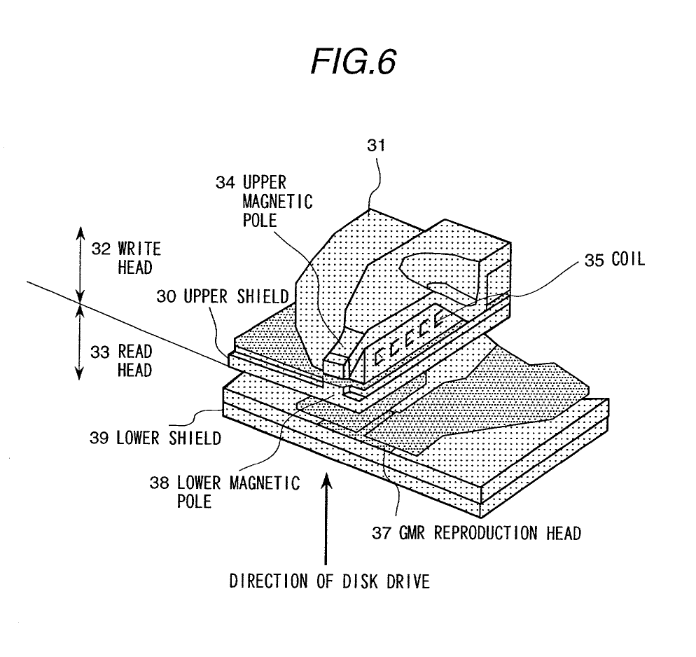

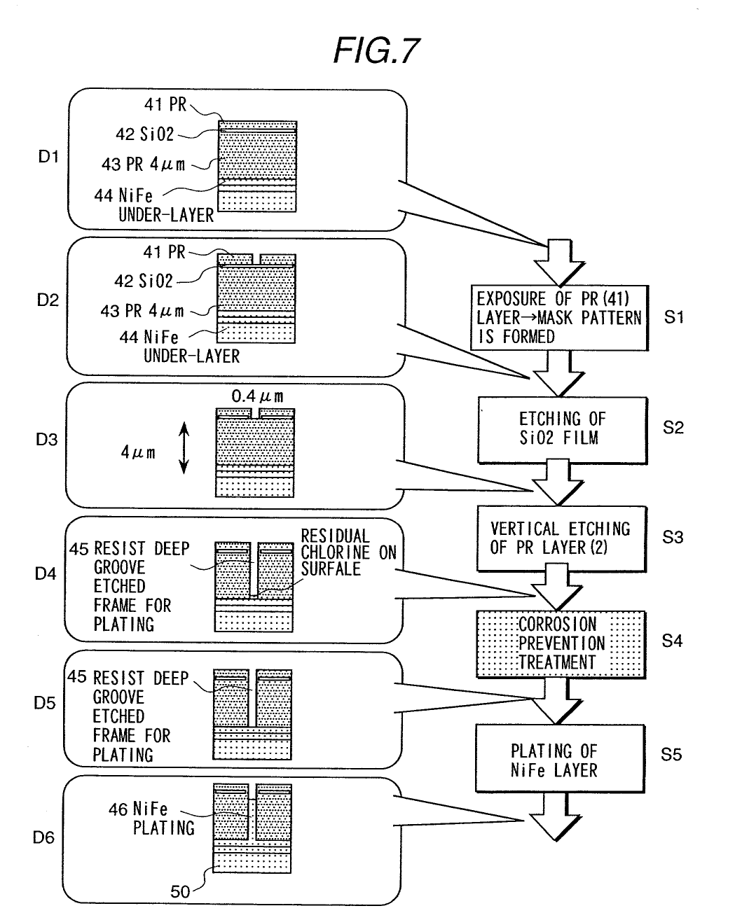

With reference to FIG. 6, an example of a typical magnetic head is shown. Magnetic head 31 is comprised of a write head 32 and a read head 33, and this write head 32 has an upper magnetic pole 34, a coil 35 and an upper shield 36 while the read head 33 has a GMR read head 37, a lower magnetic pole 38 and a lower shield 39, wherein the upper magnetic pole 34 and the lower magnetic pole 38 are manufactured in a manner to be described in the following. By way of example, the arrow in FIG. 7 indicates the direction of the disk slide.

The invention is preferably applied to the manufacture of a device having a laminated structure with an alloy layer of Fe—Ni or Ni—Fe—Co. The invention will be described in the following by way of example for the manufacture of a laminated structure having at least one layer of FeNi alloy and a photo resist layer as its mask, if necessary, which is etched by gas plasma which contains a process gas such as chlorine in etching process chamber 11.

With reference to FIG. 7, steps of forming an upper magnetic pole by the three layer resist etching process will be described with respect to each form of the structures from D1 to D6 and each step thereof from S1 to S5. A specimen used here is comprised of an upper photo resist (PR) layer 41 of 0.5-1.0 μm thick, a hard mask layer 42 which is 1000-4000 A thick made of SiO₂ or alumina (SiO₂ is shown in FIG. 7), a lower photo resist layer 43 which is 2-6 μm thick, and a seed layer 44 which is 1000-3000 A thick and is made of NiFe alloy (shown as under-layer NiFe layer in FIG. 7).

In step S1, PR layer 41 is exposed to form a mask pattern.

Then, in step S2, SiO₂ film 42 undergoes an etching process. The width of the etching in this case is, for example, 0.4 μm.

The PR layer which is, for example, 4 μm thick is subjected to vertical etching in step S3. Thereby, a resist deep groove etch plating frame is formed. 5 Namely, the lower photo resist layer is plasma-etched using a gas which contains chlorine and with the hard mask layer used as its mask so as to form a deep groove 45 until a part of the seed layer 44 is exposed in the bottom of the deep groove. In order to remove residual chlorine components deposited in the bottom of the deep groove and on an exposed surface of the NiFe alloy as indicated in D4, liquid rinsing and drying processes are applied in step S4.

Detection of a stop point in the etching process in step S2 is carried out by sensing the plasma emission in the etching process chamber 1, transmitting a signal via a glass fiber 20 which is attached thereto to a spectrometer 19, and extracting a spectroscopic emission line, for example, Of SiF. Namely, when etching approaches its terminal point, the level of emission of SiF drops, which drop can be detected and used for determination of the stopping point thereof. Likewise, a stopping point in step S3 can be determined, for example, by an emission line of CN when CO gas or N2 gas is added to its etching gas.

After that, Ni—Fe alloy is embedded in the deep groove by plating, CVD or sputtering methods, which is connected to seed layer 44 to form an upper magnetic pole (NiFe layer 46 shown in FIG. 7 is formed by plating).

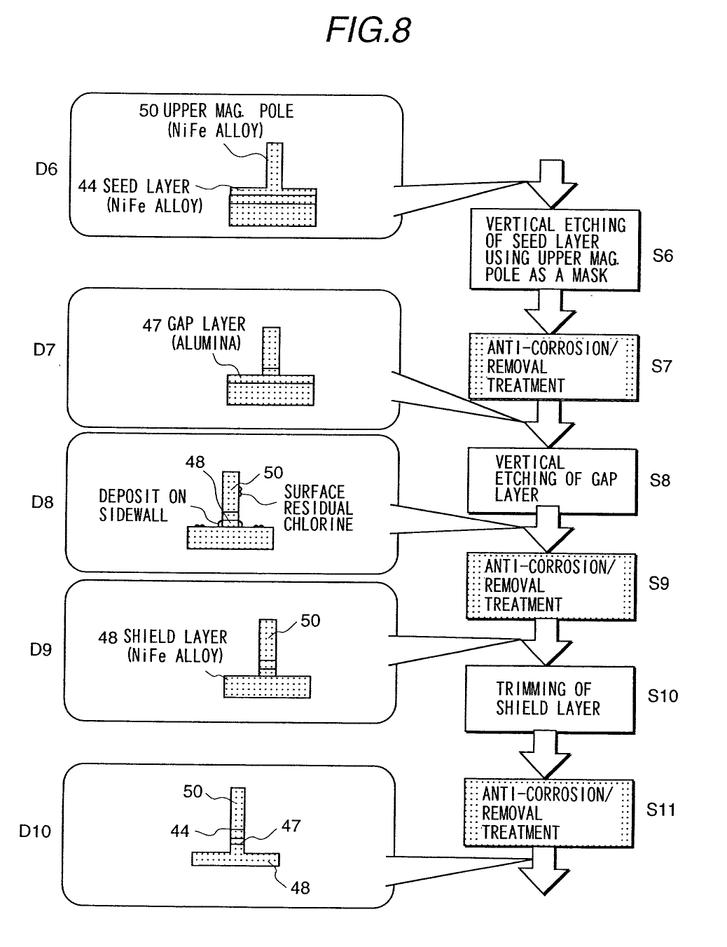

In FIG. 8, a method of vertical etching of seed layer 44, gap layer 47 and shield layer 4 8 is indicated with respect to forms of the structures from D6 to D10 and steps from S6 to S11 corresponding thereto. For the example shown in FIG. 8, a NiFe layer is used as a seed layer, A1203 layer is used as a gap layer and a NiFe under-layer is used as a shield layer.

In FIG. 8, lamination layer 51 is formed by shield layer 48 made of NiFe alloy, upper magnetic pole 50 made of NiFe alloy connected with shield layer 48, gap layer 47 made of an oxide film in close contact with the seed layer 44, and shield layer 48 made of NiFe alloy connected to the gap layer 47.

Seed layer 44 becomes an upper magnetic pole adhesion layer, and gap layer 47 is formed by an oxide film such as alumina, SiO2/TaO or the like.

A Cr-containing NiFe alloy adhesion layer, prior to forming a magnetic head layer, is subjected to plasma etching using a gas comprising chlorine gas and a rare gas such as argon in step S6. In this step, a vertical etching of the seed layer 44 using upper magnetic pole 50 as its mask is carried out. Subsequently, a corrosion prevention treatment is applied by liquid rinsing in order to remove residual etching products and residual chlorine components in step S7.

If gap layer 47 is alumina, it is subjected to plasma etching with a BCl₃/Cl₂ gas in step S8. In this case, it means that vertical etching of gap layer 47 is carried out using upper magnetic pole 50 as its mask. If gap layer 47 is SiO₂, the plasma etching is performed using fluorine gas. After that, corrosion prevention treatment is applied by liquid rinsing in order to remove residual etching products and chlorine components deposited on sidewalls in step S9.

Then, in step S10, trim-etching is applied to shield layer 48 by plasma etching using chlorine gas. It means that in this step a vertical etching of the shield layer is carried out using upper magnetic pole 50 as its mask. By this trimming, an intermediate magnetic pole 49 which has the same cross-section as that of upper magnetic pole 50 can be formed.

Subsequently, in step S11, a corrosion prevention treatment is applied by liquid rinsing in order to remove residual etching products and chlorine components.

Immediately after the etching process using a gas plasma (of the first step), that is, within 5 minutes, the liquid rinsing (of the second step) is carried out sequentially to prevent corrosion.

This gas plasma can be generated using at least one of BCl₃, Ar and O2₂ or a combination therebetween, besides chlorine gas, as described above.

The gas plasma etching process of the invention is carried out at a temperature below 150° C. to room temperatures, or lower than that.

The second step of the invention includes one or more than two of the following steps:

(A) pure water rinsing,

(B) alkaline solution cleaning followed by water rinsing,

(C) acid solution cleaning followed by water rinsing,

(D) fluorine nitric acid cleaning followed by water rinsing, and

(E) neutral detergent cleaning followed by water rinsing.

Heat drying in rinsing/drying unit 6 is conducted using hot plate 22 the temperature of which is kept below 200° C.

At least one of the following layers is included in the lamination layer other than the NiFe alloy layer, which is to be etched by gas plasma in the process chamber:

(A) a photo resist layer

(B) alumina (Al2o3) layer,

(C) silicon oxide layer,

(D) Cu layer, and

(E) Ta layer.

The substrate of the invention described above is A1203/TiC substrate, on which the layer of NiFe alloy is formed, which is subjected to the gas plasma etching in the process chamber.

As to the lamination layer of the upper magnetic pole 50 comprising the PR layer/A1203 or SiO2 layer/seed layer made of NiFe alloy, which are formed to be 1 μm/0.5-1.0 μm/2-4 μm thick, respectively, the A1203 layer can be etched by a gas plasma using chlorine gas, SiO2 can be etched using fluorine gas, and the seed layer made of NiFe alloy can be etched using a gas containing chlorine/argon gas. Here, the high density is defined to be 1 to 10 mA/cm² (ion saturation current density), and the low density to be 0.1 to 1 mA/cm² .

By applying corrosion prevention treatment for each lamination layer of FIG. 8, at the same time, removing etching products deposited on the side walls during the etching process, and consecutively carrying out etching process within the same process chamber, an excellent vertical etching according to the invention becomes possible.

Alternatively, if the thickness of the deposits on the side wall is not too thick, the respective steps in FIG. 8 of S6 for etching the seed layer, S7 for etching the gap layer, and S10 for trim-etching the shield layer may be executed continuously within a single or a plurality of etching units 1 without being taken out of the vacuum, and after that, a corrosion prevention treatment of S11 is applied.

For etching of the NiFe layer, a gas mainly containing chlorine is used. In this case, a large etching ratio (selectivity ratio) corresponding to the under-layer alumina film can be obtained. This is because, with the gas mainly containing chlorine, the alumina film is hardly etched. To the contrary, when etching the alumina film, a gas mainly containing BCl₃ is used. This is because a reaction of alumina Al203+2BCl3 and AlCl3+B203 proceeds, and of which AlCl3+B203 are evaporative in vacuum, the etching process is expedited. In this case, with BCl3 gas, the etching rate of NiFe film is low, therefore, a high selectivity ratio relative to the mask NiFe or underlayer NiFe films can be obtained. In the argon ion milling method, however, this stoichiometric etching mechanism does not work, thereby rendering a lower selectivity ratio in both cases of etching NiFe and alumina

Detection of respective stop points of etching in respective steps of FIG. 8 is executed in the following manner. When etching the NiFe layer of step S6, an emission line of Fe is monitored. When etching the alumina layer of step S8, an emission line of Al is monitored. When trim-etching the NiFe layer in step S10, its etching time is calculated and controlled on the basis of its etching rate measured in advance.

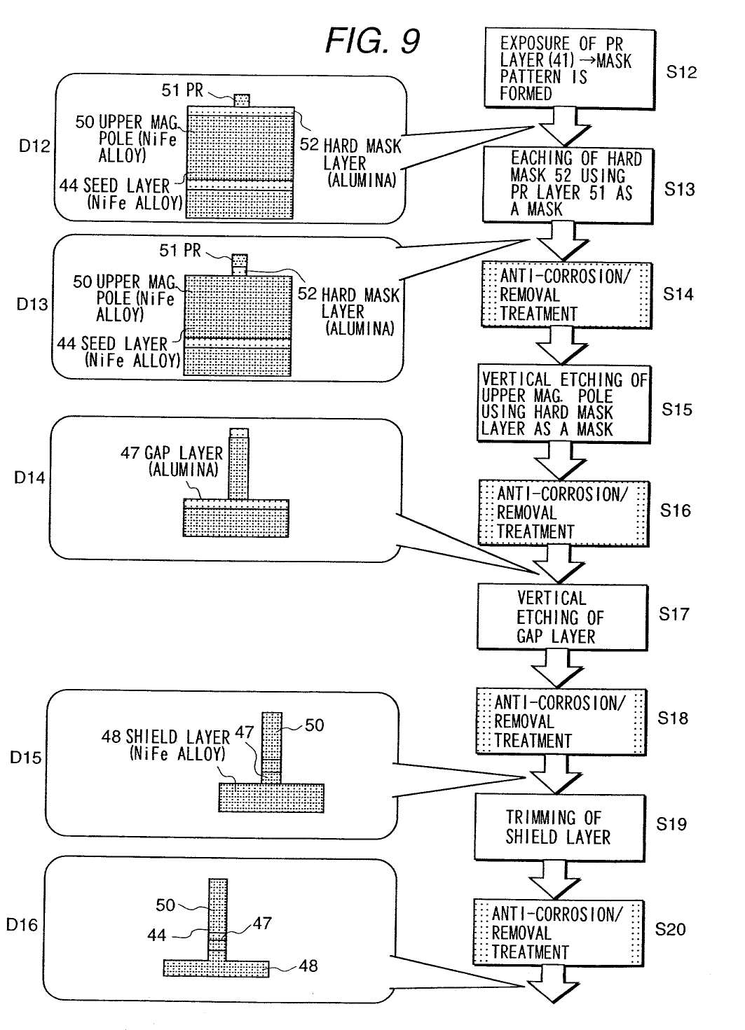

Now, with reference to FIG. 9, an example of forming an upper magnetic pole by five layer continuous etching according to the invention will be described with reference to the structures D12 to D16 and respective steps S12 to S20 corresponding thereto. The specimen is a lamination layer which is comprised of: upper photo resist (PR) layer 41 which is 0.5-1.0 μm thick; hard mask layer 42 of SiO2 or alumina which is 2000-6000 A thick (alumina layer is shown); upper magnetic pole layer 50 of NiFe alloy which is 2-6 μm thick (which includes the seed layer if the upper magnetic pole is formed by plating); gap layer 47 of SiO2 or alumina which is 1000-2000 A thick; and shield layer 48 of NiFe alloy. In step S12, PR layer 41 is exposed to form a mask pattern. Then, in step S13, etching of hard mask layer 52 is carried out. After etching of the hard mask, a water rinsing process is carried out for removal of residual compounds deposited on the sidewall and for corrosion prevention in step S14.

Then, the upper magnetic pole layer is etched by plasma processing with a gas which contains chlorine and with the hard mask used as its mask in step S15. With chlorine gas, because its etching rate is approximately 1000A/min., and its selectivity ratio relative to the alumina hard mask layer is approximately 8, a thinner hard mask layer, as thin as a few thousands A thick, will be sufficient. At the same time, because its selectivity ratio relative to the under-layer alumina gap layer is also high, being approximately 8, it becomes easy, by carrying out over-etching fully, to eliminate incomplete removal of etching debris resulting from uneven etching rates throughout the surfaces of the specimen.

When gap layer 47 is alumina, plasma etching is employed using BCl3 gas in step S17. At this instant, a part of the hard mask layer remaining on the upper magnetic pole is also removed by etching. Then, in order to remove residual deposits on the sidewall and residual chlorine components, liquid rinsing is applied in step S18. Subsequently, shield layer 48 is trimming-etched by plasma etching with chlorine gas in step S19. After that, liquid rinsing is applied in order to remove residual etching products and chlorine components in step S20.

In this invention, because NiFe alloy is included in the lamination layer, and because the high density plasma and the low energy irradiation ion method is adopted, a form of residual chlorine compound remaining after etching is considered mainly to be in a state of physical/chemical adsorption of chlorine on the surface of the alloy.

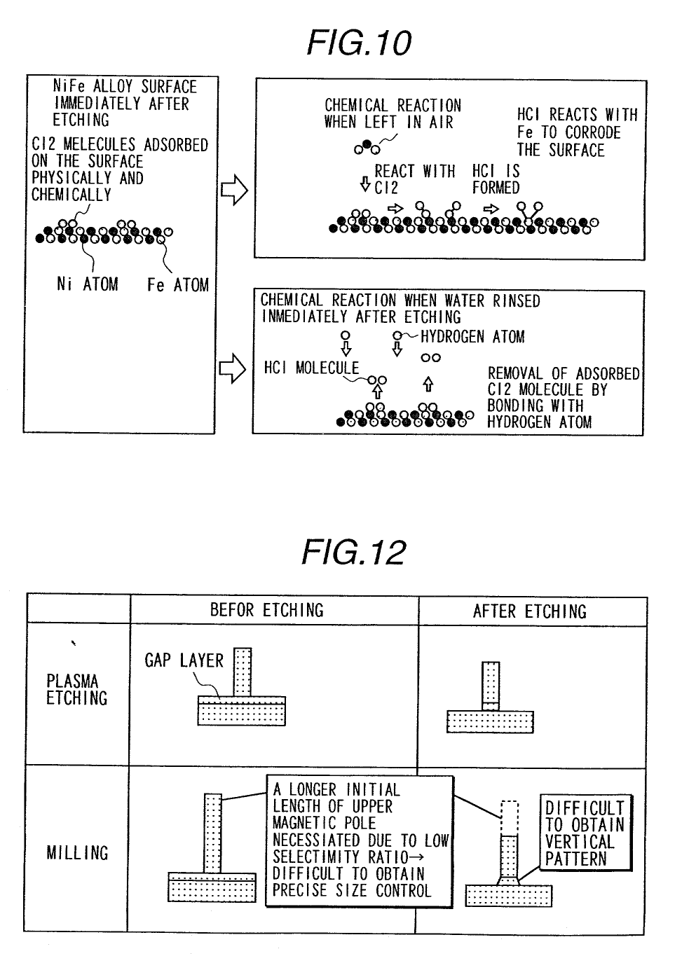

As indicated in FIG. 10, chlorine molecules exist as physically/chemically adsorbed on NiFe alloy immediately after etching. When disposed in the atmosphere, chemical reaction proceeds such that a water molecule in the air reacts with a chlorine molecule to form HCl, and HCl reacts with Fe to corrode the surface of the alloy. In contrast, according to the invention, such chlorine molecules existing in the state of adsorption can be removed by dissolution into pure water and separated from the surface. Thereby, by removal of the residual chlorine components remaining after the gas plasma etching, which can be simply enabled by the rinsing (anti-corrosion) process of the invention, the corrosion prevention process of the invention can be achieved without any additional,specific post treatment for the residual etching products.

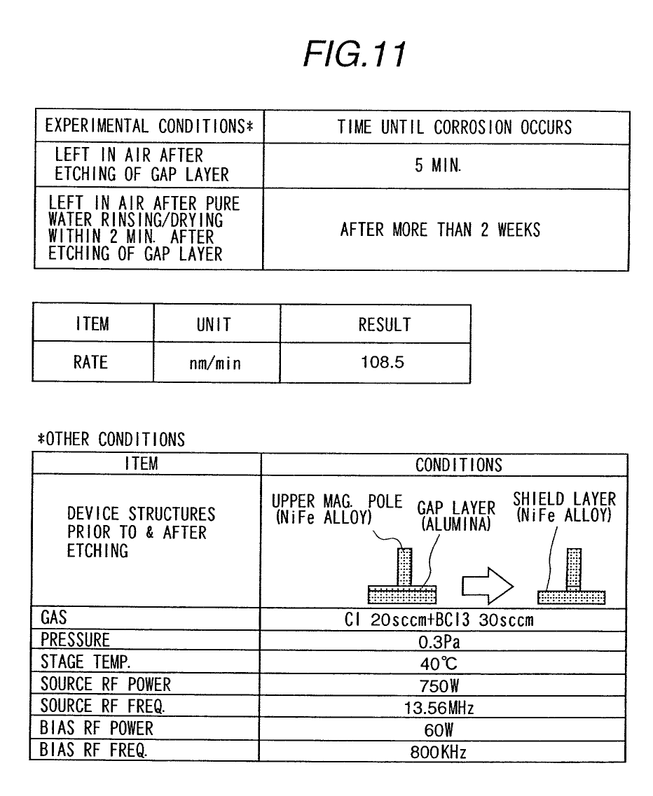

FIG. 11 compares results of experiments obtained by the prior art and the present invention. A prior art gap layer was corroded in five minutes when disposed in air after its etching. In contrast, the gap layer which was subjected to the pure water rinsing and drying process within 2 minutes after its etching according to the invention was not corroded even after the elapse of two weeks while disposed in air. Further, thanks to its high-density plasma etching, even at a temperature of 40° C. of the specimen's stage, a high etching rate of 1000A/min. is achieved. Other related conditions of the experiments are also indicated in FIG. 11.

FIG. 12 illustrates dimension control capabilities of the upper magnetic pole formed by the plasma etching method and the ion milling method, respectively. When ion milling or low-density plasma is used, its selectivity ratio relative to the mask is low. For example, when etching A1203, its selectivity ratio relative to its mask material (NiFe) is 0.2-1.0. In contrast, when high-density plasma is used, a high selectivity ratio of 1.0-10.0 is achieved. This is because the ion energy of incidence of the specimen is as high as 500V-3 kV, thereby etching the material to be etched and the mask material non-selectively and physically all the same.

In the case where the high density plasma is used, the second high frequency power source as indicated in FIG. 3 which can supply power directly to the specimen's stage independently of the primary high frequency power source for generating the high density plasma is provided separately according to the invention, and the output from this second power supply is controlled such that the ion energy of incidence on the specimen is appropriately controlled. Preferably, its ion energy of incidence is set at a low value approximately from 50 to 500 V, and at the same time, a gas to be used is selected appropriately such as, for example, BCl3 gas when etching alumina, and chlorine gas when etching NiFe alloy, in order to achieve a higher selectivity ratio for respective materials to be etched.

As described hereinabove, in the milling method, because of its lower selectivity ratio, an initial length of its upper magnetic pole at the start of etching must have a longer size. Namely, a large quantity of margin of etching for the upper magnetic pole must be provided. Therefore, it becomes difficult to have a precise dimensional control when forming the upper magnetic pole. Further, because of difficulty in obtaining verticality when etching the gap layer (sputtered substances tend to attach to the sidewall, resulting in a tapered shape), the specimen must be tilted in various directions when milling in order to obtain the desired verticality.

In contrast, according to the one embodiment of the invention, by provision of the steps of etching the lamination layer including the seed layer, gap layer and shield layer by the high density plasma process exclusively in the vertical direction with the upper magnetic pole used as a mask, and of applying the corrosion prevention treatment for removing the residual chlorine components deposited on the etched surface, it becomes possible for the gap layer to be formed to have a vertical shape as indicated in FIG. 12. Further, it also becomes possible for the intermediate magnetic pole to be formed to have the same vertical shape as that of the upper magnetic pole.

According to the invention described above, a specimen which is formed from the lamination layer which includes NiFe alloy layer is etched using a high density gas plasma, and then, immediately after the etching process, liquid rinsing is applied, thereby eliminating the influence of residual etching products due to ionization and providing a corrosion prevention treatment simultaneously. Therefore, in the case where the specimen to be processed is an upper magnetic pole, a vertical etching of the upper magnetic pole becomes significantly easy, and in addition, its verticality is ensured to be maintained in air. Therefore, it provides a further advantage in that the track width, which is one of the parameters that determine fundamental properties of the magnetic head, can be ensured to be adequately prescribed.

What is claimed is:

1. An apparatus for processing a specimen which is laminated on a substrate, comprising:
an etching process unit, which is supplied with a gas to produce a plasma, for etching a specimen laminated on a substrate having two or more layers, at least one of which comprises NiFe or NiFeCo alloy, at a temperature of said specimen below 200° C.;
a rinsing unit for rinsing an exposed surface of said lamination layer comprising said alloy, which is exposed by said etching, using a liquid; and
a dryer unit for drying said exposed surface of said lamination layer comprising said alloy after the rinsing thereof, wherein said lamination layer comprising said alloy which is dried is further subjected to gas plasma etching.

2. An apparatus for processing a specimen according to claim 1, further comprising:
an atmospheric loader;
a vacuum transport chamber having a vacuum transport robot therein; and
unload and load lock chambers connecting between said atmospheric loader and said vacuum transport chamber for delivering the specimen, wherein
said vacuum transport chamber is connected to said etching process chamber of said apparatus, and
said atmospheric loader is connected to at least a rinsing cup and hot plate provided in said rinsing/dryer units.

3. An apparatus for processing a specimen according to claim 1, wherein plural etching process chambers are provided.
